(19) United States
(12) Patent Application Publication
(10) Pub. No.: US 2014/0174508 A1
(43) Pub. Date: Jun. 26, 2014

(54) SOLAR MODULE

(71) Applicant: SAINT-GOBAIN GLASS FRANCE, Courbevoie (FR)

(72) Inventors: Andreas Sznerski, Alsdorf (DE); Holger Schumacher, Grevenbroich (DE)

(21) Appl. No.: 14/119,314

(22) PCT Filed: Apr. 3, 2012
(86) PCT No.: PCT/EP2012/056043

§ 371 Date: Feb. 6, 2014

(30) Foreign Application Priority Data
Jun. 7, 2011 (EP) 11168948.5

(51) Int. Cl. H01L 31/048; H01L 31/18

(52) U.S. Cl. CPC H01L 31/0481; H01L 31/0482; H01L 31/1876
USPC 136/251; 438/66

(57) ABSTRACT

A solar module is described. The solar module has: i) a carrier layer and, arranged thereon one over another, a first intermediate layer, at least one solar cell, a second intermediate layer, and a front pane; ii) a peripheral edge reinforcement arranged above the front pane; iii) an interspace formed by a peripheral projection of the carrier layer; and iv) a peripheral projection of the peripheral edge reinforcement beyond the front pane, the interspace having a sealant.

The invention relates to a solar module and a method for producing a solar module.

Photovoltaic layer systems for the direct conversion of sunlight into electrical energy are sufficiently well known. The materials and the arrangement of the layers are coordinated such that incident radiation is converted directly into electrical current by one or a plurality of semiconducting layers with the highest possible radiation yield. Photovoltaic and extensive-area layer systems are referred to as solar cells.

Solar cells contain, in all cases, semiconductor material. The highest efficiency levels known to date of more than 20% are obtained with high-performance solar cells made of monocrystalline, polycrystalline, or microcrystalline silicon or gallium arsenide. More than 80% of the currently installed solar cell power is based on crystalline silicon. Thin-film solar cells require carrier substrates to provide adequate mechanical strength. Due to the physical properties and the technological handling qualities, thin-film systems with amorphous, micromorphous, or polycrystalline silicon, cadmium telluride (CdTe), gallium arsenide (GaAs), copper indium (gallium) selenide sulfide (Cu(In,Ga)(S,Se)₂), and copper zinc tin sulfo-selenide (CZTS) as well as organic semiconductors are particularly suited for solar cells. The pentenary semiconductor Cu(In,Ga)(S,Se)₂ belongs to the group of chalcopyrite semiconductors that are frequently referred to as CIS (copper indium diselenide or sulfide) or CIGS (copper indium gallium diselenide, copper indium gallium disulfide, or copper indium gallium disulfoselenide). In the abbreviation CIGS, S can represent selenium, sulfur, or a mixture of the two chalcogens.

An electrical circuit of a plurality of solar cells is referred to as a photovoltaic module or a solar module. The circuit of solar cells is durably protected against environmental influences in known weather-resistant superstructures. Usually, two panes made of low-iron soda lime glass and adhesion-promoting polymer films are connected to the solar cells to form a weather-resistant solar module. The solar modules can be integrated via connection boxes or connection housings into a circuit of a plurality of solar modules. The circuit of solar modules is connected to the public supply network or to an independent electrical energy supply via known power electronics.

Flat roofs of warehouses or industrial plants have a large, exposed, shadow-free area. Consequently, they are particularly well-suited for the installation of photovoltaic systems. The roofing membrane of flat roofs consists, as a rule, of metal sheets and, for example, trapezoidal metal sheets. Flat roofs customarily have only a slight pitch of 2% to 17.6% and have only a low load-bearing capacity of, for example, 75 kg/m².

Solar modules according to the prior art, in which the solar cells are laminated between two panes made of soda lime glass, have a high weight per area of, for example, 18 kg/m². Consequently, they are unsuitable for installation on flat roofs with a low load-bearing capacity.

For the production of lightweight solar modules with a weight per area of less than 12 kg/m², front panes made of thin glass or plastics are customarily combined with carrier layers made of a material as light as possible but still torsion resistant. At the same time, the front pane and carrier layer must be adequately impermeable to moisture or water vapor to protect the solar cells and busbars in the interior of the solar module against corrosion. Suitable materials for the carrier layers are, for example, glass fiber reinforced plastics or metal layers.

US 2010/0065116 A1 discloses a thin glass solar module with a weight per area of 5 kg/m² to 10 kg/m². The thin glass solar module comprises a carrier layer, solar cells, and a front pane made of very thin, chemically strengthened glass. The very thin glass is flexible. The front pane is so flexible that the impact energy of a hailstone in the legally prescribed hail impact test is absorbed by the carrier layer on the back side of the solar module.

EP 1 860 705 A1 discloses a stable, self-supporting solar module that is arranged on its outer regions in a mounting frame. The mounting frame has notches through which liquids situated on the solar module can run off.

U.S. Pat. No. 4,830,038 A describes a solar module that is supported and encapsulated by an elastomer. The elastomer is cast in an injection molding process around the back, the sides, and a portion of the front.

DE 10 2009 014 348 A1 discloses a solar module consisting of a transparent adhesive layer, in which the solar cells interconnected by cell connectors are embedded. A transparent, UV stable, thin front layer is situated thereabove. A supporting sandwich element, consisting of a core layer and glass fiber layers bonded by polyurethane, is situated on the back side. Fastening elements and an electric socket are integrated into the supporting sandwich element.

EP 2 237 324 A1 describes a solar module with an L-shaped frame. One leg of the L-shaped frame is adhesively bonded to the solar module. The second leg forms a spacer from a roof or carrier structure.

WO 03/050891 A2 discloses a solar module with a first substrate, a second substrate, and at least one photovoltaic element between the substrates. The edge between the first and second substrate is sealed with a moisture resistant material.

DE 102 31 401 A1 describes a photovoltaic module with a light-transmissive substrate, a first sealing polymer layer, a photovoltaic cell, a second sealing polymer layer, and a weatherproof film. The weatherproof film includes a moisture-proof layer and a gas-proof layer, with the gas-proof layer made of polyphenylene sulfide.

The lateral entry edge of the solar module between the front pane and the carrier layer remains a critical entry point for the penetration of moisture into the interior of the solar module.

The object of the present invention consists in providing a solar module with improved sealing of the lateral entry edges against moisture. The improved solar module should, in particular, be lightweight and suitable for installation on a flat roof.

The object of the present invention is accomplished according to the invention by a solar module in accordance with claim 1. Preferred embodiments emerge from the subclaims. The invention further comprises a method for producing a solar module. A use of the solar module according to the invention emerges from other claims.

The solar module according to the invention comprises
a carrier layer and, arranged one over another thereon, a first intermediate layer, at least one solar cell, a second intermediate layer, and a front pane, and
an edge reinforcement, which is arranged above the front pane.

The carrier layer has a peripheral projection beyond the front pane and the edge reinforcement has a peripheral projection beyond the front pane. The interspace between the projection of the carrier layer and the projection of the edge reinforcement has a sealant.

In the context of the invention, the terms “arranged one over another” or “arranged above” describe a congruent or a section-wise arrangement.

In an advantageous embodiment of the solar module according to the invention, the carrier layer has a peripheral projection beyond the front pane of at least 0.3 cm, preferably of 0.3 cm to 5 cm, and particularly preferably of 0.3 to 1 cm. In another advantageous embodiment of the solar module according to the invention, the edge reinforcement has a peripheral projection beyond the front pane of at least 0.3 cm, preferably of 0.5 cm to 5 cm, and particularly preferably of 1 to 2 cm. The projection of the edge reinforcement and the projection of the carrier layer beyond the front pane are preferably implemented the same size such that the interspace has an approx. rectangular cross-sectional area. This has the particular advantage that in the case of a shock load, both the carrier layer and the edge reinforcement can absorb forces uniformly.

The edge reinforcement has multiple essential functions. Additional protection of the outer edge of the solar module, for example, due to impact during transport or assembly, is achieved by means of the edge reinforcement.

Moreover, an interspace, which has a sealant, is formed by the projection of the carrier layer and the projection of the edge reinforcement beyond the front pane. The sealant serves as a moisture barrier. The sealant is mechanically protected by the carrier layer and the edge reinforcement such that the moisture barrier is durably maintained.

In principle, all plastics that are UV stable and weather resistant and have adequate water and water vapor impermeable properties are suitable as the sealant. The sealant preferably contains polyurethane (PU), polyvinyl chloride (PVC), polyethylene (PE), polypropylene (PP), polyamide (PA), high density polyethylene (HDPE), low-density polyethylene (LDPE), acrylonitrile butadiene styrene copolymer (ABS), polycarbonate (PC), styrene butadiene (SB), polymethyl methacrylate (PMMA), polyethylene terephthalate (PET), thermoplastic elastomers, or an adhesive based on butyl, acryl, bitumen, or silicone and/or mixtures thereof.

The edge reinforcement includes one or a plurality of layers preferably made of metal, glass, rubber, plastic, or glass fiber reinforced plastic. The edge reinforcement particularly preferably includes the material of the carrier layer. The carrier layer advantageously has a coefficient of expansion adapted to the solar module and the front pane. As a result, only slight or no mechanical stresses appear due to different thermal expansion of the materials of the solar module.

The edge reinforcement can preferably include polyvinyl chloride (PVC), polyethylene (PE), polypropylene (PP), polyamide (PA), high density polyethylene (HDPE), low-density polyethylene (LDPE), acrylonitrile butadiene styrene copolymer (ABS), polycarbonate (PC), styrene butadiene (SB), polymethyl methacrylate (PMMA), polyurethane (PU), polyethylene terephthalate (PET), and/or mixtures thereof.

The thickness of the edge reinforcement is preferably at least 0.5 mm and particularly preferably 1 mm to 5 mm and projects upward beyond the front pane. The outer region of a glass front pane is particularly susceptible to flaking or conchoidal fractures of the glass, for example, upon impact of a hailstone in the hail impact test. A protected region is created by means of the superelevation of the edge reinforcement beyond the front pane. A hailstone with a diameter of, for example, 25 mm cannot penetrate into the particularly damage susceptible edge region of the front pane. The necessary minimum thickness of the edge reinforcement can be determined by simple experiments in the hail impact test.

In another advantageous embodiment of a solar module according to the invention, the edge reinforcement covers a peripheral edge region of the front pane over a width b of at least 0.2 cm, particularly preferably of 0.5 cm to 5 cm, and very particularly preferably of 1 cm to 2 cm. The edge reinforcement is preferably adhesively bonded to the front pane in the peripheral edge region, for example, by a butyl, acryl, or silicone adhesive or a double-sided adhesive tape. The adhesive bonding results in a stable interspace and enables simple filling of the interspace with the sealant.

Since the edge reinforcement overlaps the front pane in sections, a peripheral edge that surrounds the front pane in the form of a ring is formed. In the case of rainfall or snowmelt, water can collect in the region of the transition between the front pane and the edge reinforcement. The water cannot drain off because of the peripheral edge reinforcement. The stagnant water accumulation promotes the formation of algae. Moreover, with permanent or long-term action, water can penetrate the moisture proof seals of the solar module. Also, dirt, sand, and dust that cannot be washed away by rainwater collect in this region.

The collection of water and dirt at the transition between the front pane and the edge reinforcement especially affects solar modules on roofs that have only a slight pitch, so-called flat roofs.

Consequently, an important aspect of the present invention comprises water drain channels that are incorporated into the edge reinforcement. By means of the water drain channels, rainwater or melt water can drain off. The draining water can carry dirt, sand, and dust with it and keep the front pane of the solar module free of contaminants.

In an advantageous embodiment of a solar module according to the invention, the edge reinforcement has, on each corner of the solar module, at least one water drain channel that connects the internal side of the edge reinforcement to the external side of the edge reinforcement. Here, “external side of the edge reinforcement” means the side of the edge reinforcement that is situated on the exterior of the solar module. “Internal side of the edge reinforcement” means the side opposite the external side of the edge reinforcement.

In an advantageous embodiment of the solar module according to the invention, the edge reinforcement has at least one water drain channel on each peripheral external side of the solar module.

The width of the water drain channel is advantageously selected such that a hailstone with a diameter of 25 mm at a speed of 23 m/s does not damage the front pane with central or lateral impact on the water drain channel. The width of the water drain channel depends on the thickness of the edge reinforcement, i.e., on the height h of the superelevation of the edge reinforcement beyond the front pane, and can be determined by simple experiments. In an advantageous embodiment of the solar module according to the invention, the water drain channel has a width of 0.5 mm to 5 mm, preferably of 2.5 mm to 5 mm.

The busbars are guided out of the solar module through openings in the edge reinforcement, the front pane, and/or the carrier layer. A connection housing is arranged above the respective opening. The busbars are electrically conductively connected to a connecting lead in the connection housing. The connection is preferably made via plugs, contact pins, contact prongs, spring elements, crimp connections, solder joints, welded joints, or other electrical line connections. In an advantageous embodiment of the solar module according to the invention, the connection housing covers the complete opening. The connection housing and/or the cavity formed by the opening and the cutout can be sealed by a casting compound. The casting compound seals the solar module against penetrating moisture and contains, for example, polyurethane, acryl, silicone, or other suitable sealing materials.

The openings in the edge reinforcement, the front pane, or the carrier layer are preferably implemented rectangular, square, or circular, with all shapes inside which the busbar can be expediently arranged equally suitable.

In an advantageous embodiment of the invention, the solar cell includes a monocrystalline or polycrystalline solar cell, preferably with a doped semiconductor material such as silicon or gallium arsenide.

In an alternative embodiment of the invention, the solar cell comprises a thin-film solar cell, which preferably includes amorphous, micromorphous, or polycrystalline silicon, cadmium telluride (CdTe), gallium arsenide (GaAs), copper indium (gallium)-selenide sulfide (Cu(In,Ga)(S,Se)₂), copper zinc tin sulfoselenide (CZTS), or organic semiconductors.

Alternatively, the solar cell comprises a tandem cell composed of two solar cells of different types arranged one over another, for example, a crystalline silicon solar cell in combination with a thin-film solar cell, an organic solar cell, or an amorphous silicon solar cell.

In an advantageous embodiment of the invention, the solar cell comprises all solar cells which are themselves brittle and/or whose carrier material is brittle and which break or are damaged by slight deflection or spot loading with low forces. In this case, slight deflection means, for example, a curve with a radius of curvature of less than 1500 mm. In this case, spot loading with low forces means, for example, an indentation from the impact of a hailstone with a diameter of 25 mm and a speed of 23 m/s in a hail impact test. In this case, damage means a degradation of the photovoltaic properties of the solar cell due to mechanical damage to the semiconductor material, the carrier material, or electrical line connections, for example, by a short-circuit or a power interruption. The damage to the solar cell reduces the efficiency level of the solar cell, for example, immediately after the impact by more than 3%. Usually, a further degradation of the efficiency level takes place due to microcracks over the course of time.

The first and/or second intermediate layer contains an adhesive layer, preferably one or a plurality of adhesive films, particularly preferably made of ethylene vinyl acetate (EVA), polyvinyl butyral (PVB), ionomers, thermoplastic polyurethane (TPU), thermoplastic elastomer polyolefin (TPO), thermoplastic elastomer (TPE), or other materials with appropriate adhesive and moisture-proofing properties. The thickness of an adhesive layer can vary widely and is preferably from 0.2 mm to 1 mm and, in particular, 0.4 mm.

The external dimensions of the solar module according to the invention can vary widely and are preferably from 0.6 m×0.6 m to 1.2 m×2.4 m. A solar module according to the invention preferably includes from 6 to 100 solar cells or solar cell arrays. The area of an individual solar cell is preferably from 153 mm×153 mm to 178 mm×178 mm.

The front pane includes a material largely transparent to sunlight, preferably glass, particularly preferably flat glass, float glass, quartz glass, borosilicate glass, solar glass, soda lime glass, or polymers, preferably polyethylene, polypropylene, polycarbonate, polymethyl methacrylate, and/or mixtures thereof. The front pane can also include a film made from a polymer, preferably from a fluorinated polymer, particularly preferably from ethylene tetrafluoroethylene (ETFE), polytetrafluoroethylene (PTFE), fluorinated ethylene propylene (FEP), or perfluoroalkoxy alkane (PFA), and/or mixtures thereof. The thickness of the polymer film can vary widely and is preferably from 10 μm to 250 μm.

The front pane particularly preferably includes low-iron soda lime glass with an especially high transparency to sunlight of more than 90% in a wavelength range from 300 nm to 1500 nm.

The front pane preferably includes thermally partially prestressed or prestressed glass with a prestress of 30 MPa to 120 MPa and preferably of 32 MPa to 85 MPa. The front pane can have other additional coatings, such as antireflective layers, anti-adhesive layers, or anti-scratch layers. The front pane can have microstructuring or nanostructuring on one or both sides, which, for example, reduces the reflection of incident sunlight. The front pane can be a single pane or a laminated pane made of two or more panes. The laminated pane can include additional layers, such as transparent thermoplastic adhesive layers or plastic layers.

In an advantageous embodiment of the invention, the front pane must be adequately stable and inflexible to protect the underlying solar cells against damage. Possible causes of damage are hail impact, wind load, snow load, or bending during installation as well as being stepped on by people or animals, or the dropping of a tool. At the same time, the front pane should be as thin as possible and have a low weight in order to be suitable for installation on flat roofs with low load-bearing capacity.

As experiments of the inventor have demonstrated, solar modules according to the invention with front panes made of partially prestressed or prestressed soda lime glass with a thickness of at least 0.9 mm satisfy the technical demands with regard to torsional rigidity and stability.

Front panes according to the invention with a thickness of at least 0.9 mm offer, in particular, adequate protection for the crystalline solar cells included in the solar module in the hail impact test according to IEC 61215. The hail impact test includes bombarding the front side of the solar module with hailstones with a diameter of 25 mm and a speed of 23 m/s. The front pane according to the invention has adequate stability and inflexibility to absorb the energy of the impact of a hailstone without the crystalline solar cell in the interior of the solar module being damaged.

Alternatively, the front pane can be flexible and yielding under loads. The forces occurring can then be absorbed by the carrier layer. Yielding front panes, i.e., front panes made of flexible materials or very thin front panes are unsuitable for solar modules with brittle or crystalline solar cells. The crystalline solar cell would break due to the deflection of the front pane. This results, as a rule, in the destruction of a large area of the solar cell, even when the front pane is undamaged.

The thickness of the front pane substantially determines the weight of the solar module. In order to provide the most lightweight possible solar module suitable for installation on a flat roof with only a low loadbearing capacity, front panes made of glass with a thickness of a maximum of 2.8 mm are preferably used. A solar module according to the invention with a front pane with a thickness of 2.8 mm has a weight per area of roughly 10 kg/m². Such a solar module is suitable for installation on flat roofs with a low loadbearing reserve of at least 10 kg/m².

A front pane itself according to the invention is, as a rule, not damaged by the hail impact test so long as the hail impact does not occur in an edge region. The edge regions of glass panes are particularly sensitive to flaking and conchoidal fractures. The edge region of the front pane can be stabilized by an edge reinforcement. The edge reinforcement according to the invention protects the edge region of the front pane against damage in the hail impact test.

An important aspect of the invention comprises the adaptation of the coefficient of thermal expansion of the front pane and the carrier layer: Different coefficients of thermal expansion of the front pane and the carrier layer can, with temperature changes, result in different thermal expansion. A different thermal expansion of the front pane and the carrier layer can result in a deflection of the solar module and, thus, in damage to the crystalline solar cells. Temperature changes of more than 100° C. occur, for example, during lamination of the solar module or during warming of the solar module on the roof.

The second coefficient of thermal expansion, i.e., the coefficient of thermal expansion of the front pane, is preferably from 8×10⁻⁶/K to 10×10⁻⁶/K and for partially prestressed soda lime glass, for example, from 8×10⁻⁶/K to 9.3×10⁻⁶/K.

In an advantageous embodiment of the solar module according to the invention, the difference between the first coefficient of thermal expansion of the carrier layer of a solar module according to the invention and the second coefficient of thermal expansion of the front pane is 300%, preferably 200%, and particularly preferably 50% of the second coefficient of thermal expansion of the front pane.

In an advantageous embodiment of the solar module according to the invention, the carrier layer includes a glass fiber reinforced plastic. The glass fiber reinforced plastic includes, for example, a multilayer glass fiber fabric that is embedded in a cast resin molding material made of unsaturated polyester resin. The glass content of the glass fiber reinforced plastic is preferably from 30% to 75% and particularly preferably from 50% to 75%.

In an advantageous embodiment of the solar module according to the invention, the carrier layer has a first coefficient of thermal expansion from 7×10⁻⁶/K to 35×10⁻⁶/K, preferably from 9×10⁻⁶/K to 27×10⁻⁶/K, and particularly preferably from 9×10⁻⁶/K to 20×10⁻⁶/K.

In an alternative embodiment of the solar module according to the invention, the difference between the first coefficient of thermal expansion and the second coefficient of thermal expansion is ≦17%, preferably ≦12%, and particularly preferably ≦7% of the second coefficient of thermal expansion.

In an advantageous embodiment of the solar module according to the invention, the carrier layer includes a metal foil with a first coefficient of thermal expansion from 7.3×10⁻⁶/K to 10.5×10⁻⁶/K. The first intermediate layer can include a stack sequence of at least one first adhesive layer, one insulating layer, and one second adhesive layer. The insulating layer preferably includes a solid insulating film, made, for example, of polyethylene terephthalate (PET). The insulating layer has the task of insulating the busbars and the back side of the solar cells from the electrically conductive metal foil of the carrier layer. The metal foil preferably includes a stainless steel, preferably a high-grade steel of the EN material numbers 1.4016, 1.4520, 1.4511, 1.4017, 1.4113, 1.4510, 1.4516, 1.4513, 1.4509, 1.4749, 1.4724, or 1.4762.

Another aspect of the invention comprises a flat roof with
a roofing membrane with a pitch of 1% (0.6°) to 23.1% (13°),
at least one solar module according to the invention, arranged on the roofing membrane,
   wherein the roofing membrane and the solar module according to the invention are connected to each other at least in sections by at least one adhesive layer and/or connecting means.

In an advantageous embodiment of the flat roof according to the invention, the pitch is from 2% (1.1°) to 17.6% (10°), preferably from 5% (2.9°) to 17.6% (10°), and particularly preferably from 5% (2.9°) to 8.8% (5°).

The adhesive layer, with which the solar module according to the invention and the roofing membrane are connected, preferably includes acrylate adhesives, a butyl adhesive, a bitumen adhesive, or a silicone adhesive, or a double-sided adhesive film. The connecting means preferably include screw, clamp, or rivet connections and/or retaining rails, guide rails, or eyelets made of plastic or metal, such as aluminum, steel, or stainless steel.

In an advantageous embodiment of the flat roof according to the invention, the roofing membrane includes a plastic, preferably polymethyl methacrylate (PMMA, Plexiglas®), polyester, bitumen, polymer-modified bitumen, polyvinyl chloride (PVC), or thermoplastic olefin elastomers (TPOs), preferably with a flat, box-shaped or corrugated profile.

In an alternative embodiment, the roofing membrane includes a metal sheet, preferably a metal sheet made of copper, aluminum, steel, galvanized steel, and/or plastic-coated steel. The metal sheet has, for example, a trapezoidal profile and is referred to in the following as “trapezoidal metal sheet”. Additional layers can be arranged over or under the roofing membrane, for example, layers for thermal insulation. The layers for thermal insulation preferably include plastics or plastic foams, for example, made of polystyrene or polyurethane.

The screw connection of the solar module to the roofing membrane of a flat roof according to the invention is preferably carried out in a region of the edge reinforcement of the solar module and, in particular, in the region of the projection of the carrier layer beyond the front pane. This has the particular advantage that no hole need be incorporated in the front pane. Incorporating a hole in the glass front pane is a time-consuming, cost-intensive process step. Moreover, the stability of the front pane is reduced by the hole.

Another aspect of the invention comprises a method for producing a solar module according to the invention, wherein at least the sealant is filled in the interspace between the projection of the edge reinforcement beyond the front pane and the projection of the carrier layer beyond the front pane.

An advantageous embodiment of the method for producing a solar module according to the invention comprises at least:
a carrier layer and, arranged one over another thereon, a first intermediate layer, at least one solar cell, a second intermediate layer, and a front pane are laminated, wherein the carrier layer is arranged with a peripheral projection beyond the front pane,
an edge reinforcement is arranged above the front pane with a projection beyond the front pane, and
the interspace between the projection of the edge reinforcement beyond the front pane and the projection of the carrier layer beyond the front pane is filled by a sealant.

In the context of the invention, lamination includes all methods known per se for bonding the layer structure of a solar cell, preferably through the action of heat and/or pressure, for example, by autoclave processes, calendar methods, or vacuum bagging methods.

In an advantageous embodiment of the method according to the invention, the edge reinforcement is arranged in sections on a peripheral edge region of the front pane and bonded to the front pane, for example, by a butyl, acryl, or silicone adhesive or a double-sided adhesive tape. This has the particular advantage that a stable interspace that can be filled, in the second process step, by the sealant is formed.

In an alternative embodiment of the method according to the invention, the edge reinforcement is pressed or held on the front pane, for example, by means of a frame. In the second process step, the interspace created is filled by the sealant. Consequently, the sealant bonds the edge reinforcement with the remainder of the solar module such that the edge reinforcement is fixedly bonded to the solar module.

In principle, all plastics that are UV stable and weather resistant and that have adequate water and water vapor impermeable properties are suitable as the sealant.

In a preferred embodiment of the method according to the invention, the sealant includes a one-component, two-component, or multicomponent plastic. Equally suitable as the sealant are thermoplastic elastomers that are introduced into the interspace in a hot liquid state and cure there.

The sealant is preferably introduced into the interspace in liquid or paste form, manually or with a mechanical device, and cures there.

The sealant preferably includes a one-component polyurethane sealing compound that cures with atmospheric humidity to a durably flexible elastomer, for example, Sikaflex 222, from the company Sika Deutschland GmbH.

Another aspect of the invention comprises the use of a solar module according to the invention on a flat roof, preferably on a metal flat roof, of a building or a vehicle for transportation on water, on land, or in the air. Flat roofs of warehouses, industrial plants, and garages or shelters such as carports whose roofs have a large, exposed, shadow-free area and a low roof pitch are especially suitable for the installation of solar modules according to the invention.

Another aspect of the invention comprises the use of the solar module according to the invention on a flat roof with a pitch from 1% (0.6°) to 23.1% (13°), preferably from 2% (1.1°) to 17.6% (10°), particularly preferably from 5% (2.9°) to 17.6% (10°), and very particularly preferably from 5% (2.9°) to 8.8% (5°).

### BRIEF DESCRIPTION OF THE DRAWINGS

The invention is explained in detail in the following with reference to drawings and an example. The drawings are not completely true to scale. The invention is in no way restricted by the drawings.

They depict:

FIG. 1A a schematic representation of an exemplary embodiment of the solar module according to the invention,

FIG. 1B a cross-sectional representation viewing the section plane A of FIG. 1A,

FIG. 2 a cross-sectional representation of an alternative exemplary embodiment of a solar module according to the invention viewing the section plane A of FIG. 1A,

FIG. 3 a cross-sectional representation of an alternative exemplary embodiment of a solar module according to the invention viewing the section plane A of FIG. 1A,

FIG. 4 a cross-sectional representation of an alternative exemplary embodiment of a solar module according to the invention viewing the section plane A of FIG. 1A,

FIG. 5 a cross-sectional representation of an alternative exemplary embodiment of a solar module according to the invention viewing the section plane A of FIG. 1A, and

FIG. 6 a detailed flow chart of the method according to the invention.

### DETAILED DESCRIPTION OF THE DRAWINGS

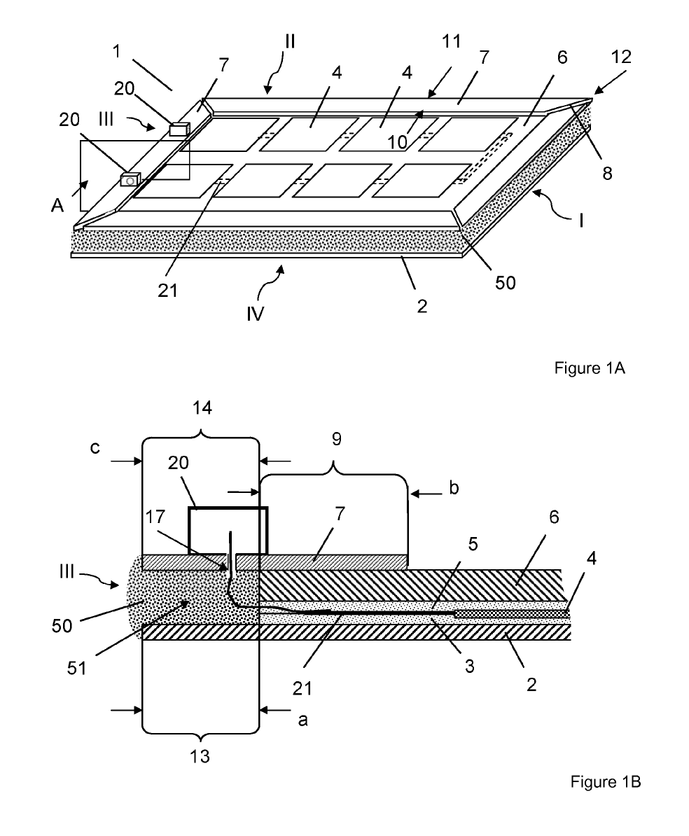

FIG. 1A illustrates a solar module according to the invention referred to as a whole by the reference number 1. FIG. 1A depicts a perspective view of the front, i.e., of the side facing the sun, of the solar module 1. The back of the solar module 1 is, in the context of the present invention, the side facing away from the front. The sides surrounding the outer edges of the front and the back are referred to in the following as external sides I, II, III, IV of the solar module 1. On the external sides I, II, III, IV of the solar module 1 are the so-called entry edges, on which moisture and water vapor can penetrate particularly easily into the solar module 1.

The solar module 1 comprises a plurality of serially connected solar cells 4, of which eight are depicted in FIG. 1A. The solar cells 4 are, in this example, monocrystalline silicon solar cells. Each solar cell has a nominal voltage of, for example, 0.63 V, such that the solar module 1 has a total nominal voltage of 5 V. The voltage is guided out via busbars 21 to two connection housings 20 in the edge region of side III of the solar module 1. The electrical line connection to the connecting leads, not show in the figures for reasons of clarity, takes place in the connection housings 20. The connecting leads are connected to a power grid or to other solar modules.

The busbars 21 are electrically conductively connected to the solar cells 4. A busbar 21 customarily includes a metal strip, for example, a tinned copper strip with a thickness of 0.03 mm to 0.3 mm and a width of 2 mm to 16 mm. Copper has proven its value for such busbars since it has good electrical conductivity as well as good processability into foils. At the same time, the material costs are low. Other electrically conductive materials that can be processed into foils can also be used. Examples for this are aluminum, gold, silver, or tin and alloys thereof.

FIG. 1B depicts a cross-sectional representation viewing the section plane A of FIG. 1A. The solar module 1 according to the invention comprises a layer structure made up of carrier layer 2, first intermediate layer 3, solar cell 4, second intermediate layer 5, and front pane 6. The carrier layer 2 has a peripheral projection 13 beyond the front pane 6 of, for example, 0.5 cm. The solar module 1 according to the invention has an edge reinforcement 7. The edge reinforcement 7 is arranged above the front pane 6 in the region 9 over a width b of, for example, 5 mm. The edge reinforcement 7 protrudes beyond the front pane 6 in the region 14 by a length c of, for example, 0.5 cm.

The interspace 51 between the projection 13 of the carrier layer 2 beyond the front pane 6 and the prediction 14 of the edge reinforcement 7 beyond the front pane 6 is filled with a sealant 50. The sealant 50 is preferably arranged in the entire peripheral interspace on the sides I, II, III, and IV of the solar module 1. The sealant 50 includes, for example, a sealing compound of polyurethane, for example, Sikaflex 222, of the company Sika Deutschland GmbH. The sealant 50 reliably seals the solar cells 4 in the interior of the laminate composed of the carrier layer 2, first intermediate layer 3, and second intermediate layer 5, and front pane 6 against moisture.

The edge reinforcement 7 is adhesively bonded to the front pane 6. The adhesive bonding seals the area between edge reinforcement 7 and front pane 6 and stabilizes the interspace 51 during the introduction of the sealant 50.

The carrier layer 2 of the solar module 1 contains, for example, a glass fiber reinforced plastic. The glass fiber reinforced plastic contains, for example, a multilayer glass fiber fabric that is embedded in a cast resin molding material made of unsaturated polyester resin. The carrier layer 2 has, for example, a glass content of 54%, a weight per area of 1.65 kg/mm², and a thickness of 1 mm.

A first intermediate layer 3 is arranged above the carrier layer 2. The first intermediate layer 3 includes, for example, an adhesive film made of ethylene vinyl acetate (EVA) with a thickness of 0.4 mm.

A plurality of crystalline solar cells 4, of which one is partially depicted in FIG. 1B, are arranged above the first intermediate layer 3. The crystalline solar cell 4 consists, for example, of a monocrystalline silicon solar cell with a size of 156 mm×156 mm. All solar cells 4 of a solar module 1 according to the invention are electrically conductively connected to each other via busbars, in serial connection or parallel connection, depending on the intended use. In addition, blocking diodes or bypass diodes can be integrated into the solar module 1.

A second intermediate layer 5, which includes, for example, an adhesive film made of ethylene vinyl acetate (EVA) with a thickness of 0.4 mm, is arranged above the solar cells 4.

A front pane 6 is arranged above the second intermediate layer 5. The front pane 6 includes, for example, a low-iron soda lime glass with a thickness from 0.9 mm to 2.8 mm and, in particular, of 1 mm. The soda lime glass is thermally partially prestressed with a prestress of, for example, 40 MPa. Partially prestressed glass is distinguished from prestressed glass by a slower cooling process. The slower cooling process results in lower voltage differences between the core and the surfaces of the glass. The bending strength of partially prestressed glass falls between that of non-prestressed and prestressed glass. Partially prestressed glass has, in the event of breakage, a high residual load-bearing capacity and is, consequently, particularly suitable for fall-prevention glazings on buildings or in the roof area.

Films or panes made of ethylene tetrafluoroethylene (ETFE), polycarbonate, or other plastics that are adequately transparent, weather resistant and UV stable and that have adequately high tightness against moisture are equally suitable as a front pane 6.

The carrier layer 2 has a first coefficient of thermal expansion of, for example, 27×10⁻⁶/K. The front pane 6 has a second coefficient of thermal expansion of, for example, 9×10⁻⁶/K. The difference between the first and second coefficient of thermal expansion is 18×10⁻⁶/K and is thus 200% of the second coefficient of thermal expansion.

The carrier layer 2 can equally include a metal foil, for example, a foil made of a stainless steel such as Nirosta, material number 1.4016 with a thickness of 0.3 mm.

The carrier layer 2 has, in this exemplary embodiment, a peripheral projection 13 beyond the front pane 6. The width a of the projection is preferably from 0.5 cm to 10 cm and, for example, 2 cm. The edge reinforcement 7 is arranged above the projection 13 of the carrier layer 2 and above an edge region 9 of the front pane 6. The width b of the edge region 9 is preferably 0.5 cm to 10 cm and, for example, 1 cm. The edge reinforcement 7 is adhesively bonded preferably to the front pane in the edge region 9, for example, with a double-sided adhesive tape.

Two busbars 21 are guided out in the region of the interspace 51 to the external side III of the solar module 1 between the first intermediate layer 3 and the second intermediate layer 5. The busbars 21 are connected on one end to the solar cell 4. The busbars 21 are arranged inside the interspace 51 and in an opening 17 of the edge reinforcement 7. Above the opening 17 of the edge reinforcement 7, a connection housing 20 is arranged, in which an electrical line connection between busbar 21 and an external connection line is situated, which is not depicted in the figure.

A plurality of water drain channels 8 in the form of cutouts are arranged in the edge reinforcement 7. The water drain channels 8 connect the inner edge 10 of the edge reinforcement 7 to the outer edge 11 of the edge reinforcement 7. The width of the water drain channels 8 is from 1 mm to 5 mm and, for example, 3 mm. The width of the water drain channels 8 and the thickness of the edge reinforcement 7 are selected such that a hailstone with a diameter of 25 mm does not damage the front pane in the hail impact test. This can be determined in the context of simple experiments.

In the event of rain or snowmelt, the water accumulating on the front pay 6 can flow off via the water drain channels 8.

In the exemplary embodiment of a solar module 1 according to the invention depicted in FIG. 1A, a water drain channel 8 is in each case arranged in each corner 12 of the solar module 1. The water drain channels 8 are arranged, for example, at an angle of 45° relative to the external sides I, II, III, IV of the solar module 1. Moreover, each of the external sides I, II, III, IV can have one or a plurality of other water drain channels 8, which is not shown in FIG. 1A. The water drain channels 8 on the external sides I, II, III, IV of the solar module 1 can, for example, be arranged perpendicular to the external sides I, II, III, IV of the solar module 1.

The solar module 1 according to the invention has a weight per area of roughly 5.6 kg/m².

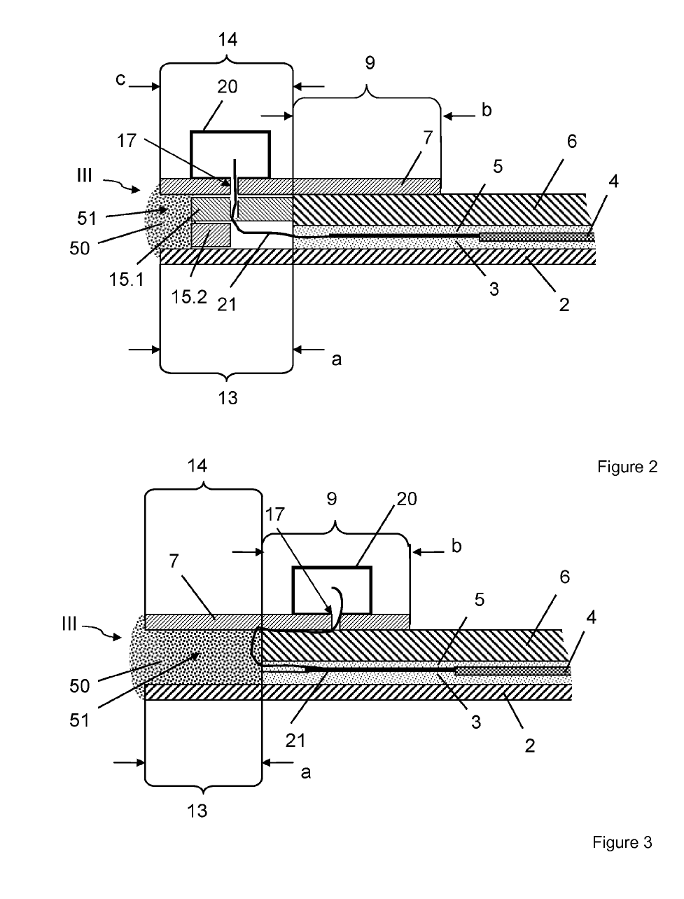

FIG. 2 depicts a cross-sectional representation of an alternative exemplary embodiment of a solar module 1 according to the invention viewing the section plane A of FIG. 1A. In this exemplary embodiment, two additional edge reinforcements 15.1, 15.2 are arranged in the interspace 51. The additional edge reinforcements 15.1, 15.2 include, on the external side III of the solar module 1, cutouts in which the busbar 21 is arranged and guided to the opening 17 in the edge reinforcement 7. The additional edge reinforcements 15.1, 15.2 stabilize the distance of the interspace 51 between the edge reinforcement 7 and the carrier layer 2.

FIG. 3 depicts a cross-sectional representation of an alternative exemplary embodiment of a solar module 1 according to the invention viewing the section plane A of FIG. 1A. In this exemplary embodiment, the busbar 21 is guided around the front pane 6. The opening 17, through which the busbar 21 is guided into the connection housing 20, is arranged above the front pane 6 in the region 9. This arrangement has the special advantage that the outer edge region of the solar module 1 can be used for fastening the solar module 1, for example, in a u-shaped guide rail. The edge reinforcement 7 is adhesively bonded to the front pane 6 in the region 9, for example, by an elastic double-sided adhesive tape, which is not shown in the figure. The adhesive tape is, on the one hand, flexible such that the busbar 21 can be arranged thereunder or thereabove. On the other hand, the adhesive tape serves for sealing against water and moisture.

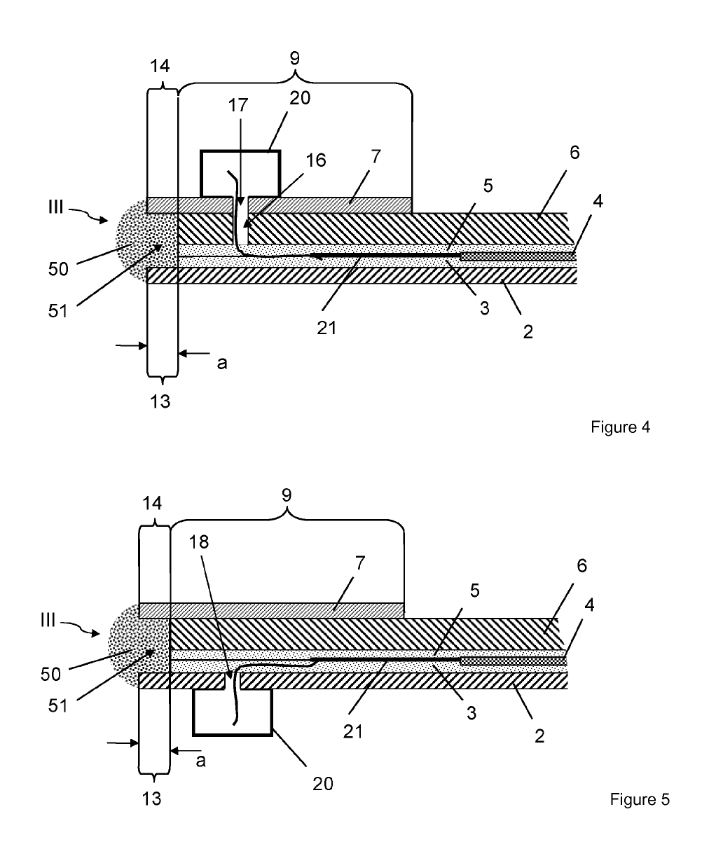

FIG. 4 depicts a cross-sectional representation of an alternative exemplary embodiment of the solar module 1 according to the invention viewing the section plane A of FIG. 1A. In this exemplary embodiment, the front pane 6 has an opening 16 inside which the busbar 21 is arranged. Above the opening 16 of the front pane 6 is situated the opening 17 of the edge reinforcement 7 and the connection housing 20. The front pane 6 is weakened by the opening 16. This weakening is compensated by the edge reinforcement 7 bonded onto the front pane 6. Since the busbar 21 is guided directly out from the interior of the solar module 1 through the openings 16 and 17 into the connection housing 20, a particularly good sealing of the exit point of the busbar 21 occurs.

FIG. 5 depicts a cross-sectional representation of an alternative exemplary embodiment of the solar module 1 according to the invention viewing the section plane A of FIG. 1A. In this exemplary embodiment, the carrier layer has an opening 18 inside which the busbar 21 is arranged. The connection housing 20 is arranged below the opening 18 of the carrier layer 2. Since the connection housing 20 and with it also the external connection lines are situated on the back side of the solar module 1, the connection housing 20 and the connection lines are protected against effects from the outside and in particular against effects on the front side of the solar module 1.

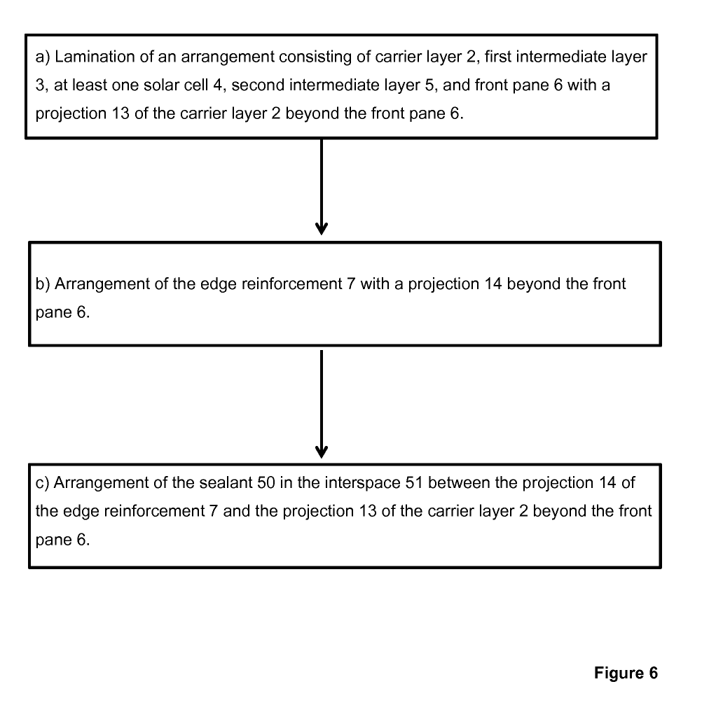

FIG. 6 depicts a detailed flow chart of the method according to the invention.

The solar module 1 according to the invention has a number of advantages compared to solar modules according to the prior art. The edge reinforcement 7 according to the invention protects the breakage sensitive outer edge of the front pane 6 against damage during transportation and assembly. At the same time, the edge reinforcement 7 according to the invention enables the virtual unhindered drainage of water during rain or snowmelt. The sealant 50 according to the invention seals the interior of the solar module 1 against moisture and water vapor. Moreover, the method according to the invention for producing the solar module 1 is particularly simple and economical to perform. At the same time, the solar module 1 is particularly lightweight with a weight per area of less than 12 kg/m² and is suitable for use on a flat roof with only a very slight pitch.

This result was unexpected and surprising for the person skilled in the art.

### REFERENCE CHARACTERS

1 solar module
2 carrier layer
3 first intermediate layer
4 solar cell
5 second intermediate layer
6 front pane
7 edge reinforcement
8 water drain channel
9 edge region of the front pane 6
10 internal side of the edge reinforcement 7
11 external side of the edge reinforcement 7
12 corner of the solar module 1
13 projection of the carrier layer 2 beyond the front pane 6
14 projection of the edge reinforcement 7 beyond the front pane 6
15.1, 15.2 edge reinforcement
16 opening in the front pane 6
17 opening in the edge reinforcement layer 7.2
18 opening in the carrier layer 2
20 connection housing
21, 21.1, 21.2 busbars
50 sealant interspace between the projection 13 of the carrier layer 2 and the projection 14 of the edge reinforcement 7 beyond the front pane 6
a width of the projection 13 of the carrier layer 2 beyond the front pane 6
b width of the edge region 9
c width of the projection 14 of the edge reinforcement 7 beyond the front pane 6
A section plane
I, II, III, IV side, external side of the solar module 1

1. A solar module, comprising:
a carrier layer and, arranged one over another thereon, a first intermediate layer, at least one solar cell, a second intermediate layer, and a front pane,
a peripheral edge reinforcement that is arranged above the front pane, and
an interspace that is formed by a peripheral projection of the carrier layer and a peripheral projection of the peripheral edge reinforcement beyond the front pane, the interspace having a sealant.

2. The solar module according to claim 1, wherein the carrier layer has a peripheral projection and/or the peripheral edge reinforcement has a peripheral projection beyond the front pane of at least 0.3 cm.

3. The solar module according to claim 1, wherein the peripheral edge reinforcement covers at least one peripheral edge region of the front pane of at least 0.2 cm.

4. The solar module according to claim 1, wherein the peripheral edge reinforcement has on each corner and/or on each external side of the solar module at least one water drain channel, which connects an internal side and an external side of the peripheral edge reinforcement.

5. The solar module according to claim 4, wherein the at least one water drain channel has a width of 0.3 mm to 5 mm.

6. The solar module according to claim 1, wherein at least one busbar is arranged in an opening of the front pane, in an opening of the peripheral edge reinforcement, and/or in an opening of the carrier layer.

7. The solar module according to claim 1, wherein the sealant contains:
i) polyurethane,
ii) polyvinyl chloride,
iii) polyethylene,
iv polypropylene,
v) polyamide,
vi) high-density polyethylene,
vii) low-density polyethylene,
viii) acrylonitrile-butadiene-styrene copolymer,
ix) polycarbonate,
x) styrene butadiene,
xi) polymethyl methacrylate,
xii) polyethylene terephthalate,
xiii) thermoplastic elastomers,
xiv) an adhesive based on butyl, acryl, bitumen, or silicone, or
xv) mixtures of i)-xiv).

8. The solar module according to claim 1, wherein the at least one solar cell includes a monocrystalline or polycrystalline, doped semiconductor material, a thin-film solar cell, cadmium telluride, gallium arsenide, copper indium (gallium) selenide sulfide, copper zinc tin sulfo-selenide, organic semiconductors, or a tandem cell.

9. The solar module according to claim 1, wherein the front pane includes glass, polymers, or mixtures thereof.

10. The solar module according to claim 9, wherein the front pane includes thermally partially prestressed or prestressed glass with a thickness of 0.9 mm to 2.8 mm.

11. The solar module according to claim 1, wherein the carrier layer has a first coefficient of thermal expansion, the front pane has a second coefficient of thermal expansion, and a difference between the first coefficient of thermal expansion and the second coefficient of thermal expansion is ≦300% of the second coefficient of thermal expansion.

12. The solar module according to claim 1, wherein the carrier layer includes a glass fiber reinforced plastic with a first coefficient of thermal expansion of 7.3×10⁻⁶/K to 35×10⁻⁶/K.

13. A method for producing the solar module according to claim 1, wherein at least the interspace between the peripheral projection of the peripheral edge reinforcement and the peripheral projection of the carrier layer beyond the front pane is filled by the sealant.

14. A method comprising:
using the solar module according to claim 1 on a flat roof, preferably on a metal flat roof, of a building or of a vehicle for transportation on water, on land, or in the air.

15. The method according to claim 14, wherein using the solar module on the flat roof with a pitch of 1% to 23.1%.

16. The solar module according to claim 2, wherein the peripheral projection beyond the front pane is from 0.3 cm to 5 cm, preferably from 0.3 cm to 1 cm.

17. The solar module according to claim 3, wherein the peripheral edge reinforcement covers at least one peripheral edge region of the front pane for 0.5 cm to 5 cm, preferably for 1 cm to 2 cm.

18. The solar module according to claim 5, wherein the at least one water drain channel has a width of 2 mm to 4 mm.

19. The solar module according to claim 8, wherein the doped semiconductor material is made of silicon or gallium arsenide.

20. The solar module according to claim 8, wherein the thin-film solar cell is made of amorphous, micromorpheous or polycrystalline silicon.

21. The solar module according to claim 9, wherein the glass is flat glass, float glass, quartz glass, borosilicate glass, solar glass, or soda lime glass.

22. The solar module according to claim 9, wherein the polymers are
i) polyethylene,
ii) polypropylene,
iii) polycarbonate,
iv) polymethyl methacrylate,
v) mixtures of polymers i)-iv), or
vi) fluorinated polymers.

23. The solar module according to claim 22, wherein the fluorinated polymers are
i) ethylene tetrafluoroethylene,
ii) polytetrafluoroethylene,
iii) fluorinated ethylene propylene,
iv) perfluoroalkoxy alkane, or
v) mixtures of fluorinated polymers i)-iv).

24. The solar module according to claim 11, wherein the difference between the first coefficient of thermal expansion and the second coefficient of thermal expansion is ≦17% of the second coefficient of thermal expansion.

25. The method according to claim 15, wherein the pitch is from 2% to 17.6%, preferably from 5% to 8.8%.
